(19) United States
(12) Patent Application Publication
(10) Pub. No.: US 2008/0035061 A1
(43) Pub. Date: Feb. 14, 2008

(54) Fabricating A Semiconductor Device

(76) Inventor: SANG CHUL KIM, Yeongdeungpo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/838,816

(22) Filed: Aug. 14, 2007

(30) Foreign Application Priority Data
Aug. 14, 2006 (KR) 10-2006-0076588

(51) Int. Cl. C23C 16/00; H01L 21/322

(52) U.S. Cl. 118/723 R; 118/723 I; 438/474; 438/475; 257/E21.212; 257/E21.319

(57) ABSTRACT

A method and apparatus for fabricating a semiconductor device are provided. First plasma ions are introduced into a process chamber including a semiconductor substrate to amorphize the semiconductor substrate. An inert gas is introduced into the process chamber to purge the first plasma ions. Second plasma ions are introduced into the process chamber to remove impurities formed on the semiconductor substrate. The second plasma ions can be hydrogen ions. Since a PAI process and a cleaning process are performed in a single chamber, process efficiency improves. In addition, a cleaning process using hydrogen ions can reduce damage on the surface of the semiconductor substrate.

### CROSS-REFERENCE TO RELATED APPLICATION

The present application claims the benefit under 35 U.S.C. § 119 of Korean Patent Application No. 10-2006-0076588, filed Aug. 14, 2006, which is hereby incorporated by reference in its entirety.

### BACKGROUND

In general, a silicide process is often applied to a semiconductor device to reduce its resistance since the operating speed of a device is very important. A silicide process is a thermal process performed after depositing metal to form a metal silicide layer on a substrate.

A Complementary Metal Oxide Semiconductor (CMOS) image sensor is a device for converting optical images into electrical signals. In a CMOS image sensor, the silicide process is typically performed on a peripheral region that excludes the pixel region which receives light.

On a substrate on which a gate electrode is stacked, a PAI (pre-amorphization implantation) process and a cleaning process are typically performed before a silicide process.

The PAI process amorphizes condensed Si by implanting ions into a substrate.

A cleaning process is a process for removing impurities, such as an oxide layer, remaining on a substrate after the PAI process. The cleaning process is performed as a wet or dry process.

The dry cleaning process for removing impurities, which typically uses argon ions, is widely used since the wet cleaning process often leaves moisture on the substrate.

Typical dry cleaning processes have a limitation in that the surface of the substrate is damaged by accelerated argon ions. Additionally, since the PAI process and the cleaning process are typically performed separately, the process time is often long. Thus, there exists a need in the art for an improved cleaning process that minimizes damage to the substrate. There also exists a need in the art for a more efficient way to perform a PAI process and a cleaning process.

### BRIEF SUMMARY

Embodiments of the present invention provide a method for fabricating a semiconductor device that minimizes damage to the surface of a substrate and performs a PAI process and a cleaning process in a single chamber.

The fabricating method can include: introducing a first plasma gas into a process chamber having a wafer including a semiconductor substrate provided therein to amorphize the semiconductor substrate; introducing an inert gas into the process chamber to purge the process chamber; and introducing a second plasma gas into the process chamber to remove impurities formed on the semiconductor substrate.

The present invention also provides an apparatus for processing a semiconductor device. The apparatus can include: a remote plasma generator for changing an introduced gas into plasma; an accelerator connected to the remote plasma generator to accelerate the plasma gas; and a process chamber for receiving the plasma gas from the accelerator.

Since the processes are performed in a single chamber, fabricating time can be reduced. A wafer does not need to be transferred from a first chamber where the PAI process is performed to another chamber where the cleaning process is performed.

The details of one or more embodiments are set forth in the accompanying drawings and the description below. Other features will be apparent to one skilled in the art from the detailed description, the drawings, and the appended claims.

### BRIEF DESCRIPTION OF THE DRAWINGS

FIGS. 1a to 1c are cross-sectional views of a semiconductor substrate, illustrating a method for fabricating a semiconductor device according to an embodiment of the present invention.

FIG. 2 is a block diagram of an apparatus for fabricating a semiconductor device according to an embodiment of the present invention.

FIG. 3 is a schematic view of a radio frequency (RF)-type remote plasma generator according to an embodiment of the present invention.

### DETAILED DESCRIPTION

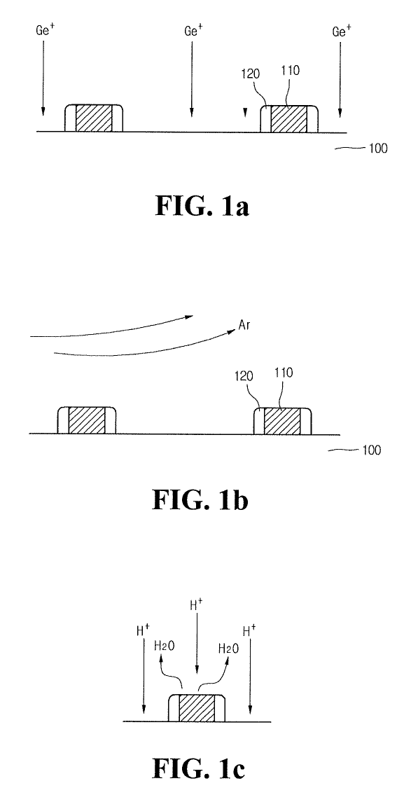

Referring to FIG. 1A, a semiconductor substrate 100, a gate electrode 110 formed on the semiconductor substrate 100, and spacers 120 formed on lateral sidewalls of the gate electrode 110, are illustrated.

In an embodiment of the present invention, a pre-amorphization implantation (PAI) process can be performed on the semiconductor substrate 100. First, the semiconductor substrate 100 can be provided into a process chamber where first plasma ions are introduced. The actual first plasma ions used will depend on the necessity of the actual process. In an embodiment, germanium ions (Ge⁺) can be used as the first plasma ions. In an alternative embodiment, nitrogen ions can be used as the first plasma ions.

The first plasma ions can be accelerated by an accelerator of an ion implantation unit and introduced to the process chamber, where they can collide with the semiconductor substrate 100.

In many embodiments, as the first plasma ions collide with the semiconductor substrate 100, a condensed silicon structure of the semiconductor substrate 100 can be changed into an amorphous silicon structure. This can lead to reduced resistance when a silicide layer is formed.

Referring to FIG. 1B, an inert gas can be introduced into the process chamber after the PAI process to purge the process chamber. By doing so, impurities remaining inside the process chamber can be removed. In an embodiment, the inert gas is argon (Ar).

Referring to FIG. 1C, second plasma ions can then be introduced to the process chamber. In an embodiment, hydrogen ions (H⁺) can be used as the second plasma ions. In a further embodiment, argon (Ar) gas can be used as a carrier gas for introducing the second plasma ions. In yet a further embodiment, argon gas can be used as a carrier gas for introducing hydrogen ions as the second plasma ions.

The second plasma ions can react with impurities formed on the semiconductor substrate 100. In an embodiment, an impurity formed on the semiconductor substrate 100 with which the second plasma ions can react is an oxide layer.

In embodiments where the second plasma ions are hydrogen ions, the hydrogen ions that have reacted with the oxide layer change the oxide layer into moisture (H₂O). This can lead to the oxide layer being removed, thus completing a cleaning process on the semiconductor substrate 100.

Since the second plasma ions that collide and react with the semiconductor substrate 100 have a relatively small mass compared to that of the argon ions typically used in the related art, the semiconductor substrate 100 is damaged to a much smaller degree by acceleration energy compared to the damage caused by argon ions. Also, in embodiments where the second plasma ions are hydrogen ions, the hydrogen ions combine with the oxygen of an oxide layer to remove the oxide layer in the form of moisture (H₂O) from the semiconductor substrate 100.

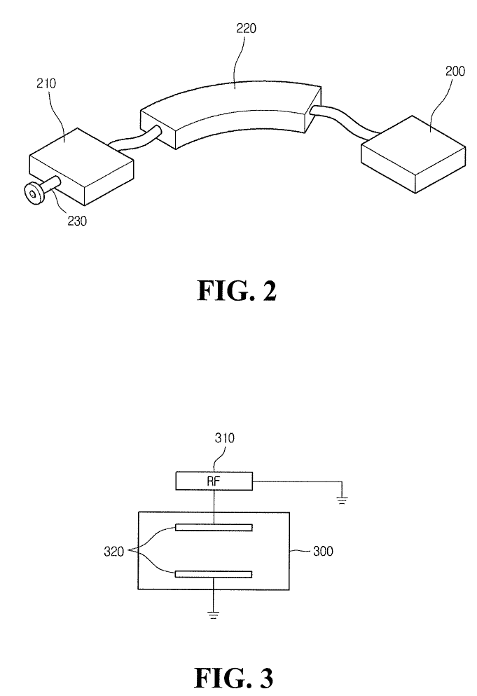

Referring to FIG. 2, an apparatus according to an embodiment of the present invention includes a remote plasma generator 210 for changing an introduced gas into plasma, an accelerator 220 connected to the plasma generator 210 to accelerate the plasma gas, and a process chamber 200 for receiving the plasma gas from the accelerator 220.

The plasma generator 210 includes an inlet portion 230 through which a gas required for a PAI process and/or a cleaning process can be introduced. In an embodiment, the plasma generator 210 changes a gas introduced through the inlet portion 230 into plasma by using an RF method.

In many embodiments, the plasma generator 210 generates germanium ions during a PAI process and generates hydrogen ions (H⁺) during a cleaning process. In an embodiment, the plasma generator 210 uses silane gas (SiH₄) as a reaction gas to generate hydrogen ions during a cleaning process. In an alternative embodiment, the plasma generator 210 uses ammonia gas (NH₃) as a reaction gas to generate hydrogen ions during a cleaning process.

In many embodiments, plasma ions generated at the plasma generator 210 can have a constant velocity due to an electric field applied to the accelerator 220 while the plasma gas passes through the accelerator 220. The plasma ions having the constant velocity can be introduced to the process chamber 200 to be used in a PAI process and/or a cleaning process.

During a PAI process, the accelerator 220 can accelerate the plasma ions to achieve an energy in the range of about 1,000 eV to about 40,000 eV. When the maximum energy achieved by the plasma ions during a PAI process is lower than about 1,000 eV, they may not collide with a substrate with sufficient velocity to amorphize the substrate. Also, when the plasma ions achieve a greater energy than 40,000 eV during a PAI process, the substrate can become damaged.

During a cleaning process, the accelerator 200 can accelerate the plasma ions to achieve an energy in the range of about 100 eV to about 1,000 eV. When the maximum energy achieved by the plasma ions during a cleaning process is lower than about 100 eV, impurities existing on a substrate may not be effectively removed. Also, when the plasma ions achieve a greater energy than 1,000 eV during a cleaning process, the substrate can become damaged.

Referring to FIG. 3, in an embodiment of the present invention, an RF alternating current (AC) power 310 can be applied to an electrode 320 including an anode and a cathode within a remote plasma generator 300 (which can be used for the remote plasma generator 210 of FIG. 2). Since they are much easier to move, electrons can be separated from positive ions of the process gas by an applied AC voltage. The positive ions have a larger mass than the electrons and are thus relatively difficult to move. Accordingly, in the remote plasma generator 300, the process gas can become a plasma gas where positive ions and negative ions are separated from one another.

In an embodiment, the positive ions can have a constant velocity while passing through the accelerator, which has an electric field. The positive ions can then be introduced to the process chamber to react with a semiconductor substrate.

In a method for fabricating a semiconductor device according to an embodiment of the present invention, process efficiency and manufacturing yield can be improved since two processes are performed in a single chamber. Also, since hydrogen ions can be used for the cleaning process, a more stable semiconductor device can be formed compared to the typical existing cleaning process using argon ions.

In a method for fabricating a semiconductor device according to an embodiment of the present invention, the process time can be reduced since a PAI and cleaning process are performed as a single process. Additionally, since the cleaning process can use hydrogen ions and reduce the damage on the surface of a substrate, a semiconductor device having improved operating characteristics can be manufactured.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a semiconductor device, the method comprising:
introducing first plasma ions into a process chamber provided with a semiconductor substrate;
allowing the first plasma ions to amorphize at least a portion of the semiconductor substrate;
introducing an inert gas into the process chamber to purge the first plasma ions from the process chamber;
introducing second plasma ions into the process chamber; and
allowing the second plasma ions to remove at least a portion of any impurities formed on the semiconductor substrate.

2. The method according to claim 1, wherein the first plasma ions comprise germanium ions.

3. The method according to claim 1, wherein the second plasma ions comprise hydrogen ions.

4. The method according to claim 1, wherein the first plasma ions are introduced to the process chamber at an energy in the range of about 1,000 eV to about 40,000 eV.

5. The method according to claim 1, wherein the second plasma ions are introduced at an energy in the range of about 100 eV to about 1,000 eV.

6. The method according to claim 1, wherein the first plasma ions comprise nitrogen ions.

7. The method according to claim 1, wherein a carrier gas is used to introduce the second plasma ions, and wherein the carrier gas is argon.

8. The method according to claim 1, wherein the inert gas is argon.

9. The method according to claim 1, wherein any impurities comprise an oxide layer.

10. The method according to claim 9, wherein the any second plasma ions comprise hydrogen ions, and wherein the hydrogen ions remove at least a portion of the oxide layer by reacting with the oxide layer to form H₂O.

11. An apparatus for processing a semiconductor device, the apparatus comprising:
a remote plasma generator for changing an introduced gas into plasma gas; an accelerator connected to the remote plasma generator to accelerate the plasma gas; and a process chamber for receiving the plasma gas from the accelerator.

12. The apparatus according to claim 11, wherein the remote plasma generator changes the introduced gas into plasma using a radio frequency alternating current power source.

13. The apparatus according to claim 11, wherein the remote plasma generator generates germanium ions during a pre-amorphization implantation process, and wherein the remote plasma generator generates hydrogen ions during a cleaning process.

14. The apparatus according to claim 11, wherein the accelerator accelerates the plasma gas generated by the plasma generator to an energy in the range of from about 1,000 eV to about 40,000 eV during a pre-amorphization implantation process.

15. The apparatus according to claim 11, wherein the accelerator accelerates the plasma gas generated by the plasma generator to an energy in the range of from about 100 eV to about 1,000 eV during a cleaning process.

16. The apparatus of claim 11, wherein the introduced gas is silane gas (SiH₄), and wherein the plasma gas comprises hydrogen ions.

17. The apparatus of claim 11, wherein the introduced gas is ammonia gas (NH₃), and wherein the plasma gas comprised hydrogen ions.
